(19) United States
(12) Patent Application Publication
(10) Pub. No.: US 2024/0099036 A1
(43) Pub. Date: Mar. 21, 2024

(54) Fabrication Of Uniform High Density Nanostructure Array

(71) Applicant: THE REGENTS OF THE UNIVERSITY OF MICHIGAN, Ann Arbor, MI (US)

(72) Inventors: Somin Eunice LEE, Ann Arbor, MI (US); Young Geun PARK, Ann Arbor, MI (US)

(73) Assignee: THE REGENTS OF THE UNIVERSITY OF MICHIGAN, Ann Arbor, MI (US)

(21) Appl. No.: 18/368,711

(22) Filed: Sep. 15, 2023

Related U.S. Application Data
(60) Provisional application No. 63/407,303, filed on Sep. 16, 2022.

(51) Int. Cl. H10K 30/35; C02F 1/14; G02B 5/00

(52) U.S. Cl. CPC H10K 30/35; C02F 1/14; G02B 5/008; C02F 2303/04; C02F 2305/08; G02B 2207/101

(57) ABSTRACT

Plasmonic nanostructures function as an antenna-reactor nanostructure to focus and convert light into thermal/chemical energy, and thus have significant potential for sustainable solar water disinfection. However, the insufficient energy harvesting efficiency resulting from inconsistent nano-features linked with arrangement and scaling is a persistent challenge. An integrated optofluidic fabrication method is presented to produce a high density integrative plasmonic dimer array to enhance solar water disinfection. The plasmonic dimer array is constructed by a combined fabrication of self-assembly monolayer method and block-co-polymer lithography approaches. This combination leads to a two-dimensional hexagonal array of dimer structures consisting of 1.3 nm nanogap. The uniformity and high density of the nanogaps in the plasmonic dimer array allows strong light focusing and a rapid and highly efficient harvesting of photothermal energy at visible and near-infrared region.

### CROSS-REFERENCE TO RELATED APPLICATIONS

This application claims the benefit of U.S. Provisional Application No. 63/407,303, filed on Sep. 16, 2022. The entire disclosure of the above application is incorporated herein by reference.

### FABRICATION OF UNIFORM HIGH DENSITY NANOSTRUCTURE ARRAY GOVERNMENT CLAUSE

This invention was made with government support under 1454188 awarded by the National Science Foundation and FA9550-16-1-0272 awarded by the Air Force Office of Scientific Research. The government has certain rights in the invention.

### FIELD

The present disclosure relates to techniques for fabricating uniform, high density nanostructure arrays.

### BACKGROUND

One of the grandest challenges in current society is to sustain the quality of life by overcoming the energy and environmental issues, simultaneously, since energy consumption and environmental remediation usually stand in a trade-off to each other. In general, to perform highly enhanced environmental remediation, larger consumption of energy resources is required. For example, while more than two billion people's life quality in the world is involved in waterborne illnesses (e.g., diarrhea) diseases) causing over half a million deaths each year, highly intensive energy resources are in demand to mitigate such water contamination issues, especially in developing and undeveloped countries. In this circumstance, solar disinfection (SODIS) in water control and water treatment has garnered great attention owing to easy access, abundance, and cleanliness. As a decentralized approach, solar disinfection utilizes the converted thermal energy from sun light via optical reactors. However, solar disinfection suffers from poor performance in many low-resource societies, which is linked to the length of time, the necessity for a clean, intact, and acceptable bottle, and less-systematic operation methods.

The incorporation of nanostructures in solar disinfection allows for a highly efficient and sustainable process. Recently, there has been demonstrated significant efforts to incorporate localized surface plasmon resonance (LSPR) nanostructures into solar disinfection. Photothermal effect in the plasmonic nanostructure has been demonstrated as a potentially promising approach for solar disinfection, since the highly focused collection of sunlight and the straightforward energy conversion into heat is allowed. According to the plasmon decay mechanism, the photothermal effect in the LSPR nanostructure stems from the amplified movement of the conduction electrons and these results in the frequency of collisions with the lattice atoms. This lattice-lattice vibration in the nanostructure leads to the photothermal effect. The generated heat power directly relies on the light absorption which is function of shape, size, and compositions of the plasmonic nanostructure, especially in sub nano or nano feature. Researchers have investigated a variety of plasmonic nanostructures, including colloidal nano particles, nanostructure deposited substrate, nanostructured packed bed, and batch reactors, to obtain the greatly improved photothermal effect. However, due to the lack of precise control over nanofeatures, such designs are frequently associated with difficulties in achieving highly efficient energy conversion processes. Furthermore, these are handicapped by the recycling procedures of the used nanoparticles, limited scalability, and difficult operation, which limit their simplicity and sustainability.

From the necessity for precise feature control of the nanostructure with uniform integrity and scalability in an optical reactor, plasmonic nanogap structure leading to the plasmonic coupling between adjacent nano structures and highly enhanced electromagnetic (E) fields holds a great potential. The plasmonic nanogap allows the larger absorption cross-section with broad range of visible-infrared (Vis-IR) extinction spectrum. As an antenna and reactor (A-R), the nanogap structure is a combined architecture where plasmonic nanogap “antennas”, act as lenses, amplify the interaction between light and “reactor” adjacent plasmonic nanostructures. The geometric arrangement and species composition of the A-R nanostructure determines the localized or collective heat generation. Up to date, numerous theoretical studies reported better understanding of the plasmonic nanogap effect. Meanwhile, experimentally studies have shown several probes by investigating several standard structures based on a single dimer, bowtie, and nano shell structure in applications focused on sensing, imaging, and photodetection. Most reported studies dealing with nanogap nanostructures that have been focused on localized heating effect. However, considering the sustainable solar disinfection which is pursuing scalable rapid water heating to reach critical disinfection condition, it is necessary to achieve collective heating from the nanogap structure to the surrounding water. Despite the rapidly expanding interest and consequences on sustainable approaches outlined above, the plasmon nanogap is still in its early stage. The structural investigation and scalable integration of plasmon nanogap for solar disinfection, particularly in the sub-nanometer gap region and the gap-gap interaction, is far from perfect. Indeed, to make a breakthrough in this area, one must explore and achieve an accurate structural rearrangement of plasmonic nanogap with the well-defined nanogap and dimer-dimer distance, simultaneously.

This section provides background information related to the present disclosure which is not necessarily prior art.

### SUMMARY

This section provides a general summary of the disclosure, and is not a comprehensive disclosure of its full scope or all of its features.

A method is presented for fabricating a uniform, high density nanostructure array. The method includes: mixing metal ions with block copolymer to form a mixture; transferring the mixture onto a substrate; plasma treating the substrate to remove the block copolymer and thereby forming a metal nanostructure array on the substrate; funtionalizing exposed surface of the metal nanostructure array on the substrate; and attaching additional metal nanoparticles onto the exposed surface of the metal nanostructure array. For some applications, a microfluidic chamber is formed over the functionalized substrate.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a diagram depicting a sustainable solar water disinfection scheme.

FIGS. 2A and 2B are diagrams of a highly ordered plasmonic dimer array for use in solar water disinfection applications.

FIGS. 3A-3H are diagrams depicting an example method for fabricating a uniform, high density nanostructure array.

FIGS. 4A-4C are SEM images of AuNP array prepared by BCP lithography.

FIGS. 4D-4F are SEM images of highly ordered plasmonic dimer array (hPDA) prepared by BCP lithography.

FIGS. 5A and 5B are graphs showing the distribution of structure-structure distances of the AuNP array and the hPDA, respectively.

FIG. 6A is an image depicting the calculated electric field of the hPDA.

FIG. 6B is a graph showing the spectra of the hPDA.

FIGS. 7A-7I are graphs showing the measured extinction spectra from nine different spots in a hPDA sample.

FIG. 8 is a diagram of an optofluidic reactor with an integrated hPDA.

FIG. 9 is cross-sectional temperature distribution in the reactor at different λ=i) 10, ii) 2, iii) 1, iv) 0.2, and v) 0.1 min at I=100 mW/cm² (scale bars=100 μm).

FIG. 10 is a graph showing the outlet temperature of the reactor as a function of h from 10 to 2,000 μm.

FIG. 11 is a graph showing the outlet temperature of the reactor as a function of I from 25 to 125 mW/cm².

FIGS. 12A-12C are graphs showing the temperature gradient as a function of wavelength of incident light for hPDA, AuNP array and without nanostructure at reactor outlet.

FIGS. 13A-13D are graphs showing the hPDA disinfection performance.

Corresponding reference numerals indicate corresponding parts throughout the several views of the drawings.

### DETAILED DESCRIPTION

Example embodiments will now be described more fully with reference to the accompanying drawings.

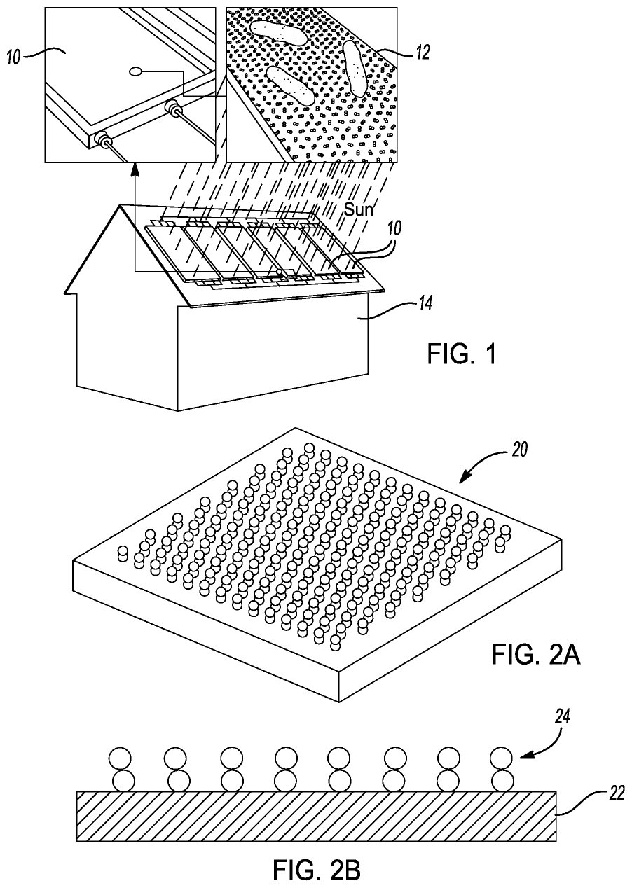

FIG. 1 depicts a sustainable solar water disinfection (SODIS) approach enabled by highly enhanced photothermal effect of high-density and uniform plasmonic dimer array 12 in the optofluidic panel 10. The optofluidic panels 10 prospectively equipped onto a roof in a residential structure 14. In an example embodiment, the optofluidic panel 10 is an integrated optofluidic reactor with a highly ordered plasmonic dimer array (hPDA) that maximize the interaction between incident light and water. As a thermal energy storage system, the hPDA results in very efficient and long-term water heating. The light induced thermal energy generation enables inactivate water pathogens in the contaminated water. The highly focused electromagnetic field in the nanogap antennas and highly enhanced photothermal effect in the nano reactor of the hPDA leads to collective heating for sustainable solar water disinfection.

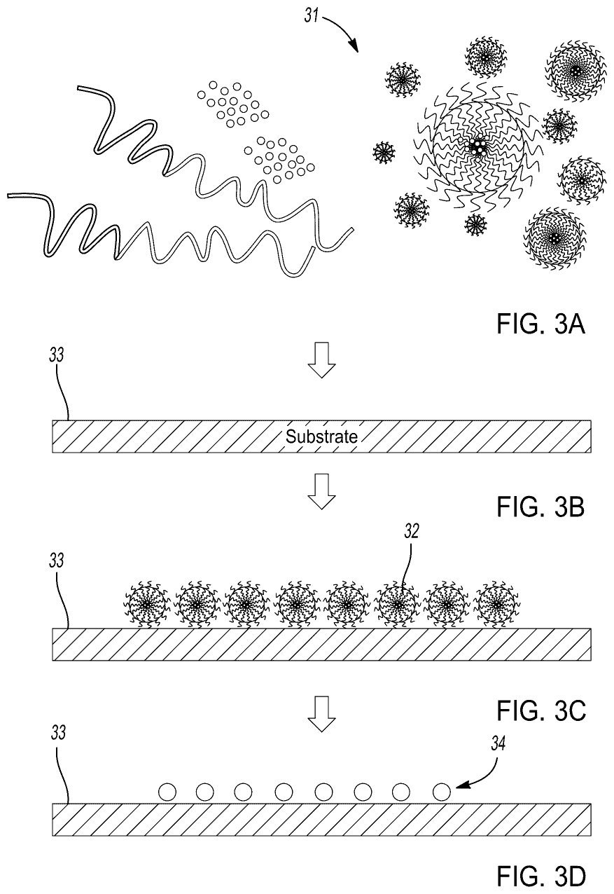

FIGS. 2A and 2B further depicts a highly ordered plasmonic dimer array (hPDA) 20 for use in solar water disinfection. In one embodiment, the hPDA 20 is made using a combination of block-copolymer lithography and the self-assembled nanogap layer 22 to add gold nanoparticles (AuNPs) 24. This disclosure systematically characterizes the morphologies and geometric arrangement of the hPDA 20 showing the orderness with high density. Furthermore, optical properties of the hPDA 20 show uniform strong plasmonic coupling. The larger absorption cross section and focused electric field in the plasmonic nanogap array in hPDA allows rapid photothermal energy harvesting with high efficiency. This highly enhanced photothermal effect in the hPDA integrated with an optofluidic reactor results in highly enhanced efficiency of the water pathogen disinfection.

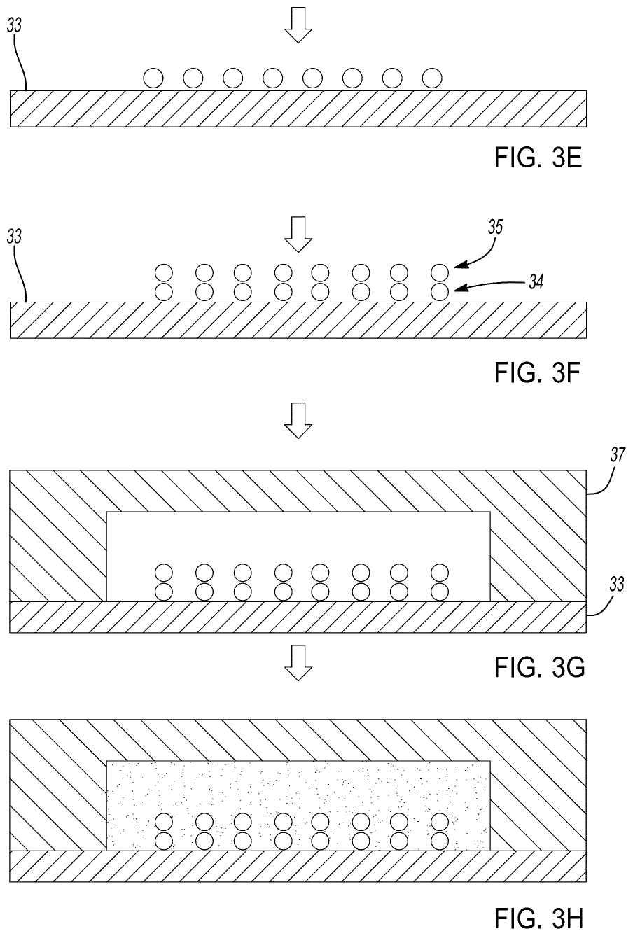

In one aspect of this disclosure, an improved method is presented for fabricating a uniform, high density nanostructure array (e.g., hPDA 20) as shown in FIGS. 3A-3H. In FIG. 3A, a mixture 31 is first formed by mixing metal ions with block copolymer. More specifically, the metal ions are dissolved with the block copolymer in a liquid to form micelle. In an example embodiment, polystyrene-b-poly(2-vinypyridine) (S units: 213,000; VP units: 153,000) were dissolved in toluene at a concentration of 4 mg/mL and stirred overnight. Gold chloride trihydrate powder with a molar ratio of 0.4 per vinyl pyridine unit was then added and stirred for an additional 72 hours. These materials and related details are merely intended to be illustrative and not intended to be limiting.

Next, the micelle 32 is transferred onto a substrate 33 as seen in FIG. 3C. In the example embodiment, the Au-BCP micelles was transferred as a uniform monolayer onto a substrate 33, for example by spin coating. In the example embodiment, the substrate 33 is silicon although other materials fall within the scope of this disclosure. Other transfer techniques are also contemplated by this disclosure.

To remove the copolymer, the substrate 33 is treated with plasma and thereby forms a metal nanostructure array 34 on the substrate 33 as seen in FIG. 3D. For example, the substrate is treated with O2 plasma (P=500 W, 0.3 mbar) for 30 minutes.

After forming a self-assembled monolayer of metal 34 on the substrate 33, the exposed surface of the metal nanostructure array is functionalized as shown in FIG. 3E. To do so, the substrate may be immersed in an ethanol solution of thiol (e.g., 1-octanethiol, 1 mM, 1 mL) for 16 hours. This disclosure contemplates other functionalization techniques as well.

In FIG. 3F, additional metal nanoparticles 35 are attached to the functionalized surface of the metal nanostructure array 34. In preparation, the substrate is washed. For example, the substrate is washed with piranha solution (H2SO4:H2O2=3:1) for 3 min, then rinsed with water and ethanol several times before drying with N2 gas. After washing the substrate, the substrate is immersed in gold nanoparticles colloidal solution (108 pM, 2 mL) for 3 hours. The gold nanoparticles in turn attach to the functionalized surface of the metal nanostructure array. After the gold nanoparticles adsorption onto the exposed functionalized surface of the nanostructure array, the substrate was again cleaned with water and dried with N2. To prepare the colloidal gold nanoparticles, a seed growth method was used and the gold nanoparticle seeds were prepared according to the Turkevich method. A mixture solution of HAuCl4 and sodium citrate was added into the solution of gold nanoparticle seeds under stirring at 100 degrees Celsius. Again, this technique for attaching metal nanoparticles to the functionalized surface is intended to be illustrative and may vary in other embodiments.

Lastly, a microfluidic chamber 37 may be formed over the nanostructure array residing on the substrate 33 as seen in FIG. 3G. In one exemplary use, this optofluidic reactor can be integrated into a panel and used for solar water disinfection. It is readily understood that the fabrication technique described above can be used to make other types of uniform, high density nanostructure arrays and such nanostructure arrays can be used for other applications as well.

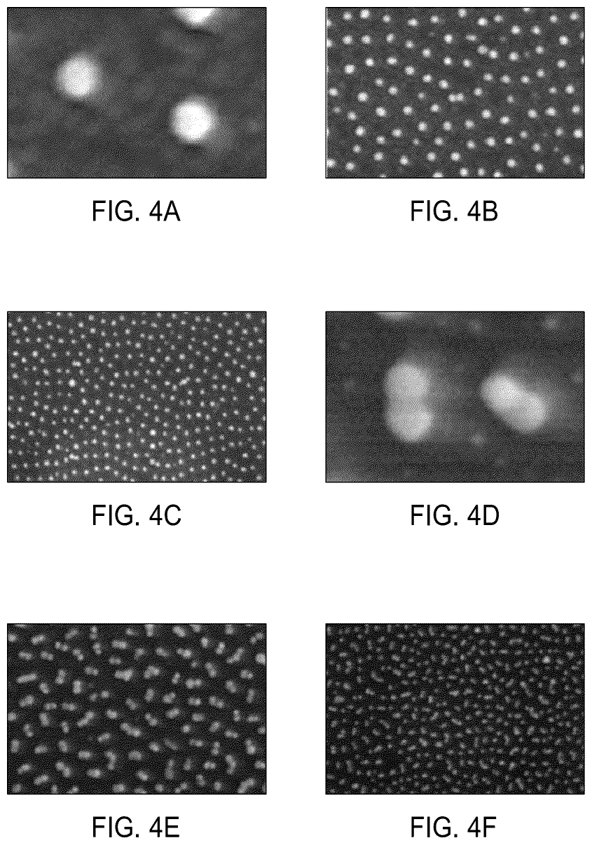

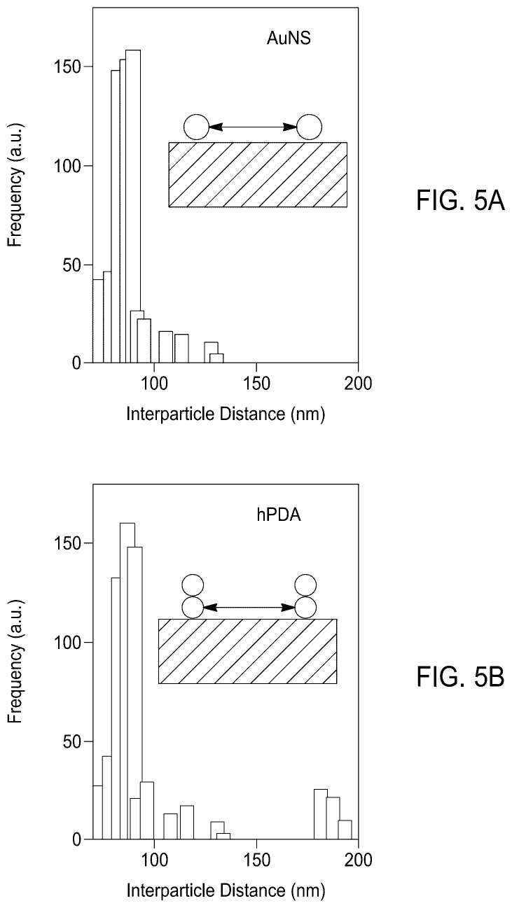

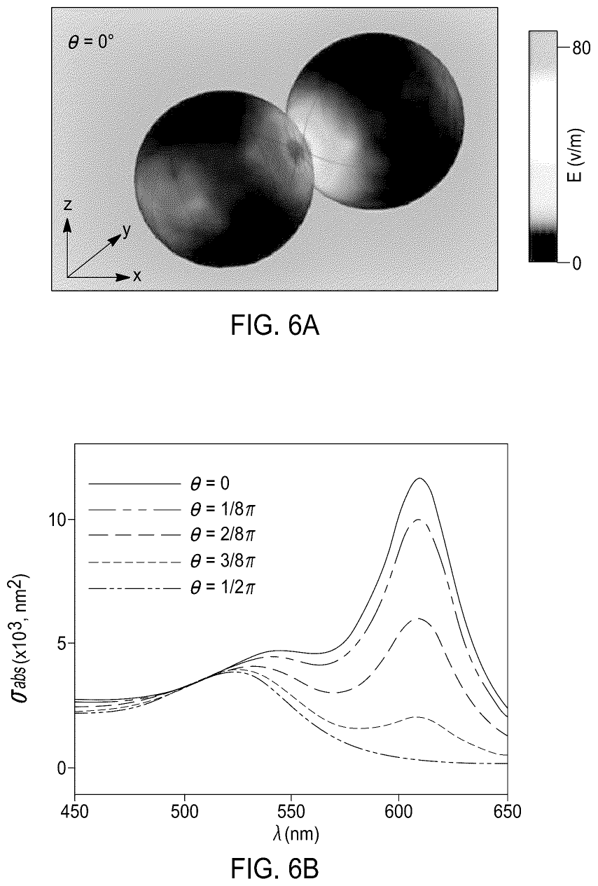

The fabrication technique described above was used to construct a highly ordered plasmonic dimer array (hPDA). To validate this technique, the morphology of the fabricated hPDA was obtained from scanning electron microscope (SEM) images seen in FIG. 4A-4F. From these images, it was observed that the orderness and dimer-dimer distance of the first AuNS array was maintained as size (˜30 nm) before/after assembling the secondary AuNP (˜40 nm). To quantify the yield of the dimer, the number of single and dimer structures on the substrate were plotted in FIGS. 5A and 5B, respectively. In particular, around 90% of particles were dimers. The dimer-dimer distances of the hPDA revealed consistent distribution (100 nm±5%). Having this structural consistency of hPDA after the middle of manufacturing processes, the secondary AuNPs effect on the shape and uniformity of the final structures were studied. While assembling the secondary AuNPs, the density of the secondary AuNPs (d_{AuNPs}) was changed from 107 to 1010 particles/mL. With d_{AuNP}, the numbers of assembled AuNP (nₐₛₛₑₘ) are increased while the uniformity decreases. For example, the single nanoparticle is the majority structure at d_{AuNPs}=107 particles/mL, while multi-nanoparticle arrays containing 4 and 10 is majority at 1010 particles/mL. Thus, the nₐₛₛₑₘ increases with d_{AuNPs}, while the uniformity in both the dimer-dimer distance and the nₐₛₛₑₘ are decreased.

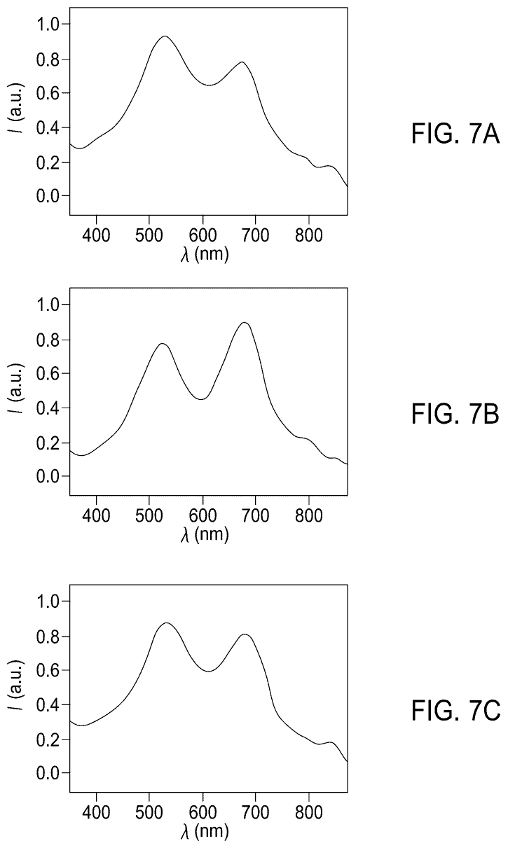

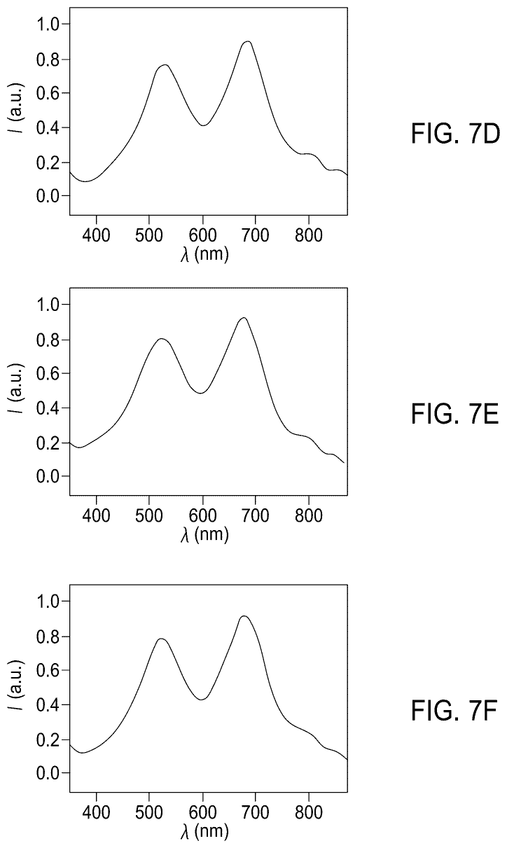

Furthermore, the light focusing and optical absorption capability of the hPDA is analyzed. To analyze such features at discrete level, first calculate optical properties using finite element analysis (FEA) based on a boundary element method by solving Maxwell's equations. The calculated local electric (E) field and scattering spectrum around single gold nanoparticle (40 nm) and a plasmonic dimer formed by 40 nm gold nano clusters with 1.3 nm lengthen SAM (Bridge=C8) layer are shown in FIG. 6A. A high-intensity E-field distribution exists in the nanogap of the Au dimer. When the polarization direction is parallel to the interparticle axis, the highest E-field in the nanogap is ˜20 times greater than that of one perpendicular to the interparticle axis. In addition, the coupling effect results reveal multi modes of E-field distribution. Under perpendicular incident light (I) and (II), E-field spectrums show identical peaks at 528 nm and 624 nm in FIG. 6B. The first peak at λ=528 nm is similar to that of single AuNP, and the second one shows larger redshift at λ=624 nm due to plasmonic coupling.

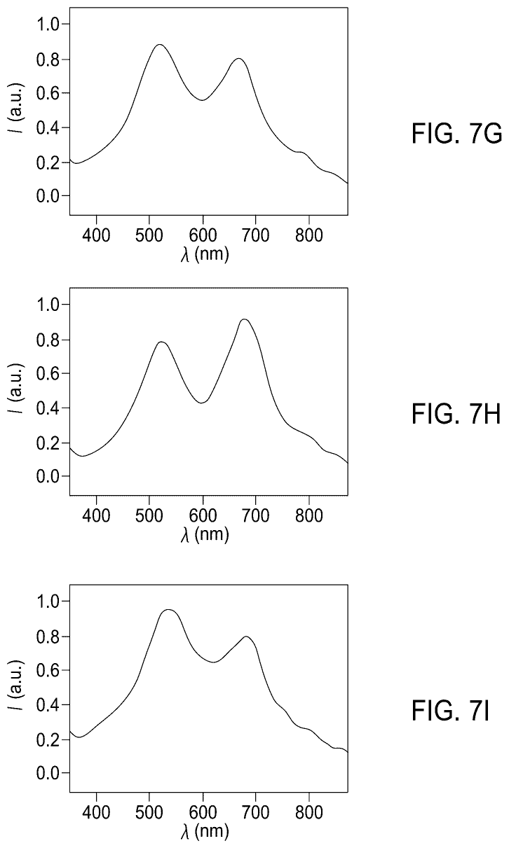

Subsequently, the optical properties of the prepared hPDA were experimentally characterized by using a dark field microscope. With reference to FIGS. 7A-7I, the scattering spectra of hPDA was obtained from 9 separate regions of interests (ROIs) that are evenly dispersed within a 1 cm distance in the sample (width×height=2 cm×2 cm) under white-light illumination. The spectra exhibit two distinct scattering peaks regardless of the location and these acquired spectrum were well matched to that of the calculated results in FIG. 6A. In general, small changes to the arrangement of and spacing between coupled plasmonic nanoparticles would lead to substantial changes in the absorption spectrum because the dimer-dimer distances in the SAM-assembled plasmonic dimer is within a region that should give rise to strong plasmonic coupling. However, the spectrum of the constructed hPDA reveals consistent typical single dimer's one even after the construction. Comparison was also made of the area of sample and the uniformity of the second peak. As the area of sample increases, the location of the second peak consistently occurred around 700 nm with less than 10% of deviations. This result indicates that the dimer-dimer distance in the built hPDA is uniform.

Next, the photothermal effect of the hPDA was investigated in an integrated optofluidic reactor. The photothermal effect in the plasmonic dimer structure is mainly caused by three processes. Firstly, the two nanostructures are coupled through near-field interaction. Next, due to the heat flux generated by the neighboring nanostructure, the photothermal effect of each nanostructure is enhanced compared to single nanoparticle. As the last stage, the generated heat is diffused out through the nanostructures to environment such as water and substrate. Most of all, the generated heat power (P) in the nanostructure is directly originated from the large absorption cross section (σ_{abs}) of plasmonic nanogap (P=/σ_{abs}I). The absorption power depends on the d_{gap}. The multi-physics FEA results indicate that the high σ_{abs} of a plasmonic dimer (d_{gap}=1.3 nm) induced large energy dissipation and led to high temperature gain (ΔT_{dimer}=50° C.) compared to that (ΔT_{AuNP}=30° C.) in single AuNP. As discussed above, the hPDA has a consistent distribution and density. However, in the x-y plane, the dimer's orientation is uneven. Spectral analysis was used to explore the effect of the hPDA's uneven orientation on the photothermal effect. In particular, the extinction spectra of the dimer structure (d_{gap}=1.3 nm) for perpendicular and parallel polarizations was plotted. An invariance of the absorption cross section is observed for λᵢₛₒ=537 nm. This indicates that any incoming linearly polarized light can be split into two light beams that are crossed polarized along the structure's two primary axes. As a result, if the absorption cross sections for the transverse and longitudinal modes are identical, increasing the polarization angle has no effect on the absorption cross section. In other words, finding crossing sites of the transverse and longitudinal spectra is sufficient to ensure that the structure's response is polarization angle invariant. This result indicates that for this specific wavelength the energy absorption (and thus the temperature increase) is not dependent on the incident light polarization. The presence of the nanogap does not preclude consistent heat creation as a function of light polarization, which opens the road for the application of solar optics, because the heat generation has nothing to do with the electric field within the gap, but rather with the electric field inside the metal. Due to the high thermal conductivity (˜30 mW/K) of Au structure, with minimal localization, this enhanced photothermal effect is diffused rapidly (˜hundreds of second) through the structure and collective thermal diffusion occurs at surrounded water. Such process indicates that the plasmonic nanogap structure is an excellent approach to transform solar energy into thermal energy and store it in water in this way. The high density and uniformly distanced array of the nanogap leads to consistent temperature profiles in large area for effective thermal energy storage.

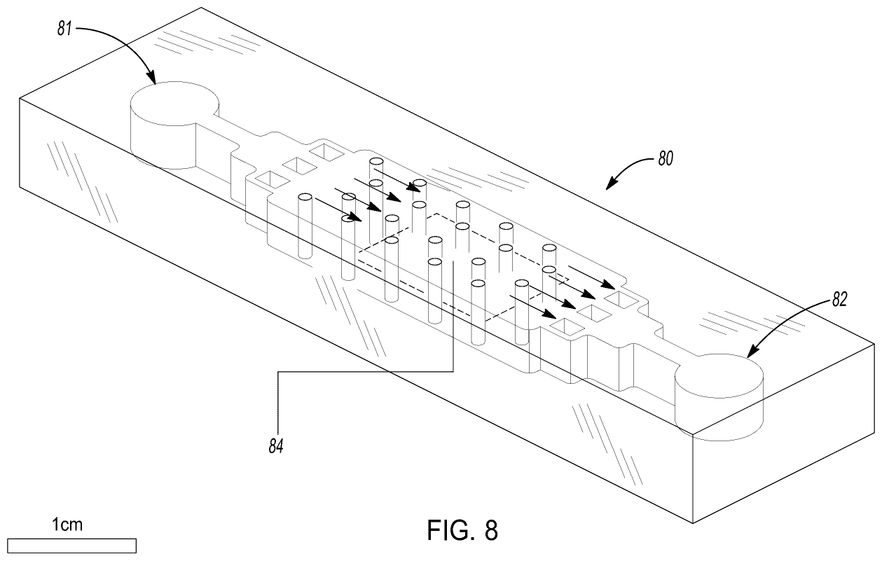

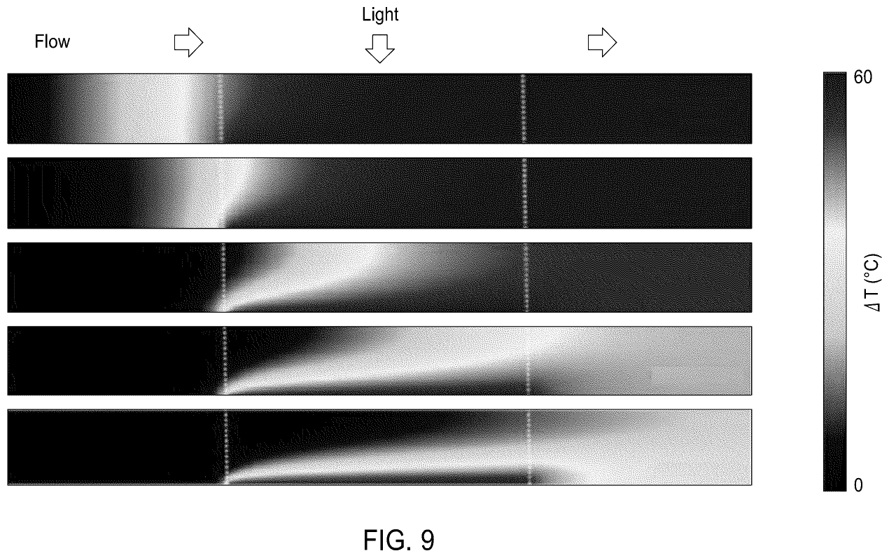

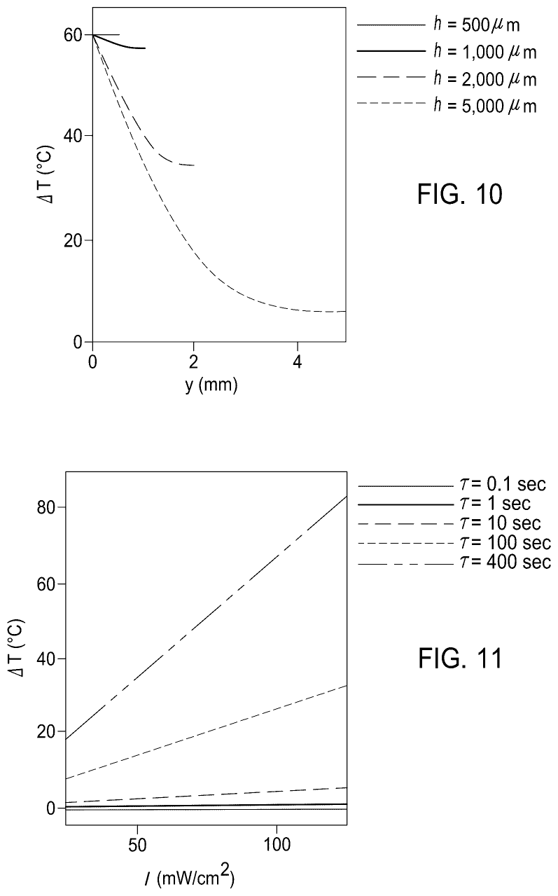

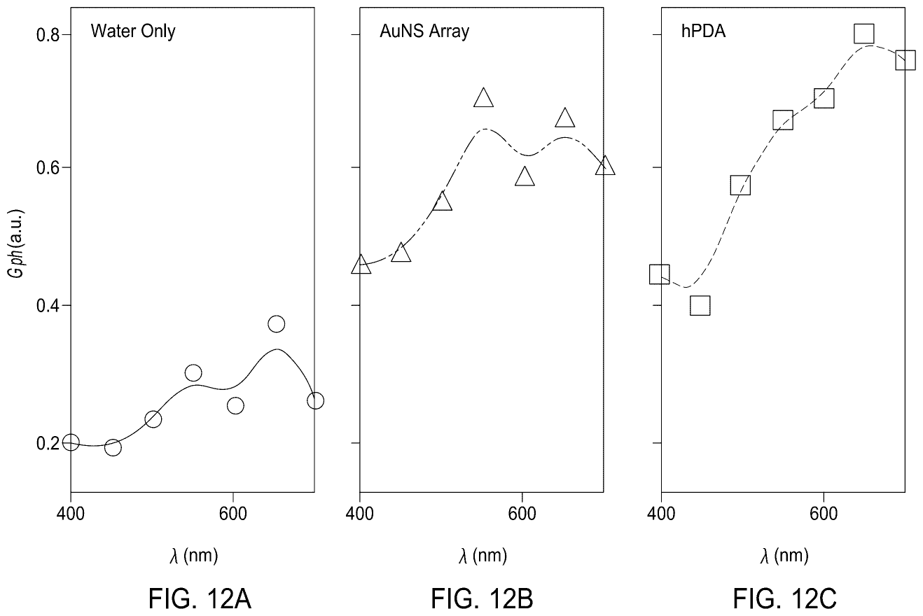

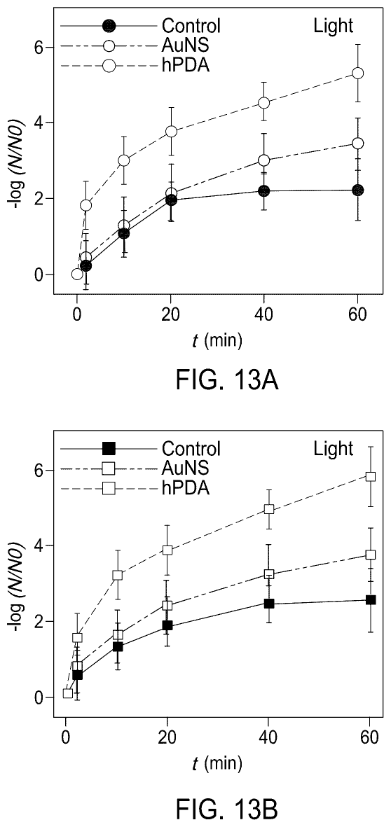

To test the thermal energy storage, an integrated optofluidic reactor 80 was design and constructed as seen in FIG. 8. The integrated optofluidic reactor 80 includes an inlet 81, an outlet 82, and an optical reaction chamber 83 with an hPDA 84 integrated on the bottom thereof. Dynamic temperature profiles are characterized as a function of the residence time (t), chamber height (h), and light intensity (I). First, the temperature profile is highly t sensitive. With higher t, uniformity of temperature distribution increase. With reference to FIG. 9, between t=1 and 10 min, the output temperature-gain ranges ˜50° C., whereas shorter t results in lower temperature-gains. In the case of h, uniform temperature distribution occurs with shorter condition as seen in FIG. 10. The water temperature at the chamber also increases with l as seen in FIG. 11. Based on these simulation results, the optimal dimension of the optical reaction chamber (h×l×W=200×10,000×10,000 μm³) was obtained. Next, the optofluidic reactor was constructed by integrating the optimized reaction chamber made from polydimethylsiloxane (PDMS) using a soft-lithography method with the prepared hPDA substrate. Dynamic outlet temperature-gain profile of hPDA and AuNPs, respectively, was measured. The measured temperature gain in hPDA (ΔT_{hPDA}) reached around 50° C. in ˜10 min, while that (ΔT_{AuNP}) in AuNP array plateaued at 30° C. in ˜15 min at the same I=100 mW/cm² and t=400 sec. According to the differences of heat dissipation (Q) and thermal diffusion rate between these two systems, the observed results are reasonable. The hPDA led to the rapid heating effect and high solar energy conversion efficiency. Furthermore, to confirm the VIS/IR induced photothermal effect in the hPDA, the photothermal energy gain (Gₚₕ) was characterized as a function of spectrum from 450 to 700 nm as shown in FIG. 12. In this test, band-path filters were used to ensure the specific wavelength and, by considering the measure light intensity at each spectrum, we estimated Gₚₕ at different wavelengths. It was observed that the highest value of 0.81 at 650 nm in hPDA, while the AuNP array revealed 0.63 at 550 nm at the same test condition. These trends of photothermal energy gain as a function of wavelength follow the optical properties discussed above.

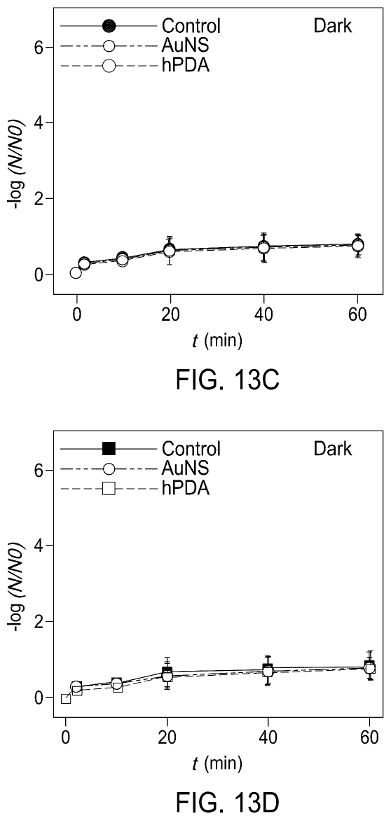

Lastly, dynamic water treatment is performed using the integrated optofluidic reactor. First, as a representative target model, Escherichia coli (E. coli) K-12 (˜5×10⁶ CFU) in a tap water-based medium was used. By estimating—log N/log N0, N and N₀ are the E. coli populations before and after the treatment, the deactivation performance was quantified and compared with them in single AuNS array, and water in FIGS. 13A and 13B. The highest E. coli deactivation performance occurred with hPDA, resulting in >5-log deactivation within 60 min under VIS/NIR light illumination, while E. coli treatment in the control (single AuNS array) results in 1.6-log inactivation. The E. coli deactivation with hPDA was rapid as similar to the temperature profile in FIG. 9. Negative control tests were also performed under the dark condition and 0.3-log and 0.2-log deactivation with hPDA and AuNP, respectively, were observed. In the control test, E. coli deactivation was higher (0.1-log) than in the treatment without nanostructure. The surface charge effect of the AuNP is responsible for the nanostructure's considerably increased deactivation. In the case of hPDA, nanostructure fabricated BCP lithography is not involved in capping agent associated with the cytotoxicity.

With reference to FIGS. 13C and 13D, deactivation of streptococcus was also tested. Unlike E. coli, streptococcus aureus which gram-positive consists of a single layered cell membrane with outer peptidoglycan layer. After 60 min, it was observed that E. coli inactivation showed lower value of 5.0-log compared to 4.7-log of streptococcus at the same condition. Gram positive bacteria are more heat resistant than gram negative bacteria. In streptococcus, higher heat stability and insulating effect of the peptidoglycan layer on the membrane is thought to lead to lower deactivation performance. Subsequently, we estimated deactivation efficiency (nd) divided by incident light intensity ((˜log N/log N₀)/Iₙₒᵣₘ) as a function of wavelength. At between λ=650 and 700 nm, the highest disinfection efficiency of 3.0 occurs for the hPDA, while single AuNS array led to disinfection efficiency of 2.5 at λ=550 and 600 nm. This trend represents that high absorption cross-section of uniform hPDS led to strong VIS/NIR induced enhanced photothermal effect and resulted in higher water treatment performance.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method for fabricating a uniform, high density nanostructure array, comprising:
mixing metal ions with block copolymer to form a mixture;
transferring the mixture onto a substrate;
plasma treating the substrate to remove the block copolymer and thereby forming a metal nanostructure array on the substrate;
funtionalizing exposed surface of the metal nanostructure array on the substrate; and
attaching additional metal nanoparticles onto the exposed surface of the metal nanostructure array.

2. The method of claim 1 further comprises transferring a portion of the mixture onto the substrate using spin coating.

3. The method of claim 1 further comprises drying the metal nanostructure array before the step of functionalizing the exposed surface of the metal nanostructure array.

4. The method of claim 1 further comprises funtionalizing exposed surface of the metal nanostructure array using a thiol molecule.

5. The method of claim 1 wherein the metal ions are further defined as gold, such that the gold ions are dissolved with the block copolymer in toluene to form the mixture.

6. The method of claim 1 further comprises forming a microfluidic chamber over the functionalized substrate.

7. A method for fabricating a uniform, high density nanostructure, comprising:
dissolving gold ions and block copolymer into a liquid to form micelle;
transferring the micelle onto a substrate using spin coating and drying it;
plasma treating the substrate to remove the block copolymer and thereby forming a metal nanostructure array on the substrate;
immersing the substrate into an ethanol solution of thiol molecules; and
attaching additional gold nanoparticles onto the exposed gold nanoparticles, thereby forming a dimer array.

8. The method of claim 7 further comprises drying the metal nanostructure array before the step of immersing the substrate.

9. The method of claim 7 further comprises forming a microfluidic chamber over the substrate.

10. A nanostructure produced by:
mixing metal ions with block copolymer to form a mixture;
transferring the mixture onto a substrate using spin coating;
plasma treating the substrate to remove the block copolymer and thereby forming a metal nanostructure array on the substrate;
funtionalizing exposed surface of the metal nanostructure array on the substrate; and
attaching additional metal nanoparticles onto the exposed surface of the metal nanostructure array.

11. The nanostructure of claim 10 is further produced by drying the metal nanostructure array before the step of functionalizing the exposed surface of the metal nanostructure array.

12. The nanostructure of claim 10 wherein the exposed surface is functionalized using thiol molecules.

13. The nanostructure of claim 10 wherein the metal ions are further defined as gold, such that the gold ions are dissolved with the block copolymer in toluene to form the mixture.

14. The nanostructure of claim 10 is further produced by forming a microfluidic chamber over the functionalized substrate.
